(19) United States
(12) Patent Application Publication
(10) Pub. No.: US 2025/0347724 A1
(43) Pub. Date: Nov. 13, 2025

(54) RECORDING MEDIUM, INFORMATION PROCESSING METHOD, AND INFORMATION PROCESSING DEVICE

(71) Applicant: Fujitsu Limited, Kawasaki-shi (JP)

(72) Inventor: Eiji OHTA, Yokohama (JP)

(73) Assignee: Fujitsu Limited, Kawasaki-shi (JP)

(21) Appl. No.: 19/190,963

(22) Filed: Apr. 28, 2025

(30) Foreign Application Priority Data
May 7, 2024 (JP) 2024-075516

(51) Int. Cl. G01R 29/00

(52) U.S. Cl. CPC G01R 29/00

(57) ABSTRACT

A computer-readable recording medium stores therein an information processing program that causes a computer to execute a process in a density functional theory calculation in which electron density is repeatedly updated. The process includes repeatedly updating the electron density until a first condition is satisfied, the first condition being that a difference ratio of a first value of a total electron energy to a second value of the total electron energy is not more than a first threshold, the first value of the total electron energy being based on a first value of the electron density updated most recently, and the second value of the total electron energy being based on a second value of the electron density updated in an initial period.

### CROSS REFERENCE TO RELATED APPLICATIONS

This application is based upon and claims the benefit of priority of the prior Japanese Patent Application No. 2024-075516, filed on May 7, 2024, the entire contents of which are incorporated herein by reference.

### FIELD OF THE INVENTION

The embodiments discussed herein are related to a recording medium, an information processing method, and an information processing device.

### BACKGROUND OF THE INVENTION

Conventionally, in the field of material development, there is a technique for calculating electron density by a numerical analysis method. The numerical analysis method is, for example, a density functional theory using a self-consistent field approach. For example, there is a density functional theory calculation that calculates electron density by repeating an operation to update electron density using a wave function according to density functional theory until it is determined that the electron density has converged.

As an example of a prior art, there is a technique that uses, as an initial value of a molecular orbital of a target system, a molecular orbital of a structure that is relatively close to the target system among structures where the calculation process of the self-consistent field approach converges. In addition, there is a technique that calculates a microphase separation structure with a dynamic mean field approximation using a lattice constant optimization method. Also, for example, there is a technique for calculating spin-polarized quantum transport in a three-dimensional nanostructure under a computer finite bias and an external voltage. Also, for example, there is a technique for numerically simulating at least one crystal structure by combining density functional theory calculations. For example, refer to Japanese Laid-Open Patent Publication No. 2008-210306, Japanese Laid-Open Patent Publication No. 2005-032058, U.S. Patent Application Publication No. 2008/0170338, and U.S. Patent Application Publication No. 2007/0185695.

### SUMMARY OF THE INVENTION

According to an aspect of an embodiment, a computer-readable recording medium stores therein an information processing program that causes a computer to execute a process in a density functional theory calculation in which electron density is repeatedly updated. The process includes repeatedly updating the electron density until a first condition is satisfied, the first condition being that a difference ratio of a first value of a total electron energy to a second value of the total electron energy is not more than a first threshold, the first value of the total electron energy being based on a first value of the electron density updated most recently, and the second value of the total electron energy being based on a second value of the electron density updated in an initial period.

An object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an explanatory diagram depicting an example of an information processing method according to an embodiment.

FIG. 2 is an explanatory diagram depicting an example of an information processing system 200.

FIG. 3 is a block diagram of an example of a hardware configuration of an information processing device 100.

FIG. 4 is a block diagram depicting an example of a functional configuration of the information processing device 100.

FIG. 5 is an explanatory diagram of an example of operation of the information processing device 100.

FIG. 6 is an explanatory diagram of an example of operation of the information processing device 100.

FIG. 7 is an explanatory diagram of an example of operation of the information processing device 100.

FIG. 8 is an explanatory diagram of an example of operation of the information processing device 100.

FIG. 9 is an explanatory diagram showing a result of a comparison with a conventional method.

FIG. 10 is an explanatory diagram showing a result of a comparison with the conventional method.

FIG. 11 is a flowchart showing an example of an overall processing procedure.

FIG. 12 is a flowchart showing an example of a structural relaxation calculation processing procedure.

FIG. 13 is a flowchart showing an example of a density functional theory processing procedure.

### DESCRIPTION OF THE INVENTION

First, problems associated with the conventional techniques are discussed. The conventional techniques may lead to an increase in the processing time required for performing density functional theory calculations. For example, when the number of atoms is N, the amount of calculation required for calculating the electron density by density functional theory calculations is O(N\hat{ }3).

Embodiments of a recording medium, an information processing method, and an information processing device according to the present invention are described in detail with reference to the accompanying drawings.

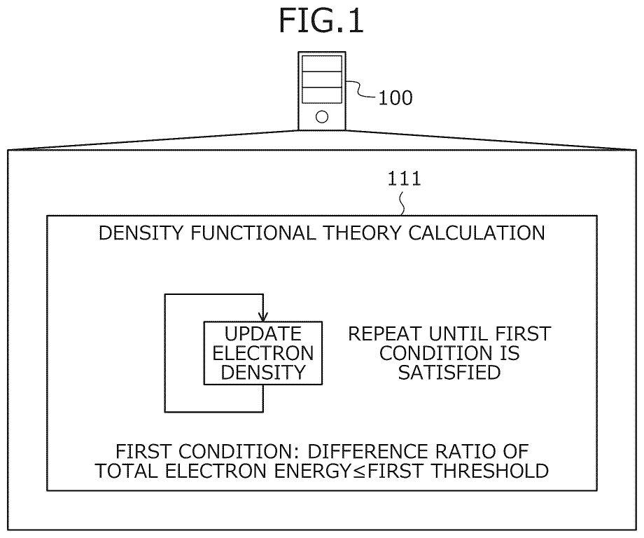

FIG. 1 is an explanatory diagram depicting an example of an information processing method according to an embodiment. An information processing device 100 is a computer for reducing the processing time required to perform density functional theory calculations based on density functional theory. The information processing device 100 is, for example, a server or a personal computer (PC).

The density functional theory calculation is, for example, a series of calculation processes for calculating electron density. The density functional theory calculation corresponds to, for example, an iterative solution method. The density functional theory calculation calculates the electron density by, for example, repeatedly performing a process of updating the electron density until a convergence condition is satisfied. The density functional theory calculation corresponds to, for example, a self-consistent field approach. The density functional theory calculation calculates the electron density of each point in a space by, for example, repeatedly performing a series of processes of updating the electron density of each point in a space using a wave function until a convergence condition is satisfied. The convergence condition is a condition for determining that a solution has converged. The convergence condition is, for example, that the difference of the most-recently calculated electron density and the electron density calculated immediately before is equal to or less than a threshold value. For density functional theory, for example, reference can be made to “Introduction to Density Functional Theory: Theory and Its Applications”, co-authored by D. S. Schur and J. A. Steckel, co-translated by Taizo Sasaki and Shigeru Suehara, Yoshioka Shoten, ISBN978-4842703657.

Here, depending on the problem to be calculated, the time required for determining that the solution has converged in density functional theory calculations may increase. For example, in density functional theory calculations, the number of iterations of a series of processes for updating the electron density at each point in a space may increase. This may lead to an increase in the processing time required when performing density functional theory calculations.

For example, when the total electron energy transitions to a state of minute fluctuation as a result of satisfying a predetermined condition, non-convergence and oscillation occur, leading to an increase in the number of iterations of a series of processes for updating the electron density at each point in the space. The predetermined condition is that an atom exists whose position differs relatively significantly in the initial structure of the molecule and in the stable structure of the molecule. The predetermined condition is, for example, that in a space, a point exists where the rate of fluctuation of the difference of the most-recently calculated electron density and the electron density calculated immediately before is relatively small, thereby making the electron density at the point difficult to converge. The predetermined condition is, for example, that in a space, a point exists where the influence on the total electron energy is relatively small, thereby making the electron density at the point difficult to converge.

Therefore, in this embodiment, an information processing method capable of reducing the processing time required for performing density functional theory calculations is described. In the following description, the density functional theory may be referred to as “DFT method”.

In FIG. 1, the information processing device 100 stores a first condition that may be a convergence condition for a density functional theory calculation 111. The first condition is, for example, that the difference ratio of the total electron energy based on the most-recently updated electron density to a representative value of the total electron energy based on the electron density updated in an initial period of the density functional theory calculation 111 is not more than a first threshold. The difference ratio is also called, for example, RDE. The most-recent time is, for example, the time when the electron density was last updated at a time point closest to the current time in the process of repeatedly updating the electron density in the density functional theory calculation 111.

The difference ratio is, for example, a value obtained by dividing the difference of the total electron energy based on the most-recently updated electron density and the representative value of the total electron energy based on the electron density updated until the immediately preceding time, by the representative value of the total electron energy based on the electron density updated in the initial period. The initial period is, for example, a time from the point of time when the electron density is updated for the first time to the point of time when the electron density is updated a predetermined number of times in the process of repeatedly updating the electron density in the density functional theory calculation 111. The initial period may be, for example, only the point of time when the electron density is first updated. The representative value is, for example, a statistical value. The statistical value is, for example, a maximum value, a minimum value, an average value, a mode value, or a median value.

The representative value of the total electron energy based on the electron density updated until the immediately preceding time may be, for example, any one of the total electron energies based on the electron density updated until the immediately preceding time. The representative value of the total electron energy based on the electron density updated initially may be, for example, any one of the total electron energies based on the electron density updated initially. In addition to the first condition, the information processing device 100 may store a second condition that may be a convergence condition for the density functional theory calculation 111. The second condition may be that the difference of the most-recently calculated electron density and the immediately precedingly calculated electron density is not more than a second threshold.

(1-1) The information processing device 100 performs the density functional theory calculation 111 so as to repeatedly update the electron density until the first condition is satisfied. The information processing device 100 may perform the density functional theory calculation 111 so as to repeatedly update the electron density until at least one of the first condition and the second condition is satisfied.

As a result, the information processing device 100 can reduce the processing time required to carry out the density functional theory calculation 111. Since the information processing device 100 utilizes, for example, the first condition, even if the total electron energy transitions to a state of minute fluctuation, the number of iterations of a series of processes for updating the electron density can be reduced. Hence, the information processing device 100 can reduce the processing time required to perform, for example, the density functional theory calculation 111. Furthermore, since the information processing device 100 utilizes the second condition, the density functional theory calculation 111 can easily be performed with high accuracy.

Furthermore, since the information processing device 100 defines the difference ratio with respect to a representative value of the total electron energy based on the electron density updated in the initial period of the density functional theory calculation 111, a common value can be set for the first threshold value to be compared with the difference ratio, irrespective of the problem to be calculated. Hence, the information processing device 100 can maintain the accuracy of determining whether the solution has converged in the density functional theory calculation 111, irrespective of the problem to be calculated, and can improve convenience.

When the convergence condition is satisfied in the density functional theory calculation 111, the information processing device 100 outputs the final electron density or the final total electron energy, etc. The output format is, for example, display on a display, printout to a printer, transmission to an external device via a network I/F, or storage to a storage area. The information processing device 100 outputs the final electron density or the final total electron energy, etc. such that the user can refer to it. In this way, the information processing device 100 can make the final electron density or the final total electron energy, etc. available to the user.

While an instance has been described in which the function of the information processing device 100 is implemented by a single computer, this is not limitative. For example, the function of the information processing device 100 may be implemented by coordination of multiple computers. For example, the function of the information processing device 100 may be implemented on a cloud.

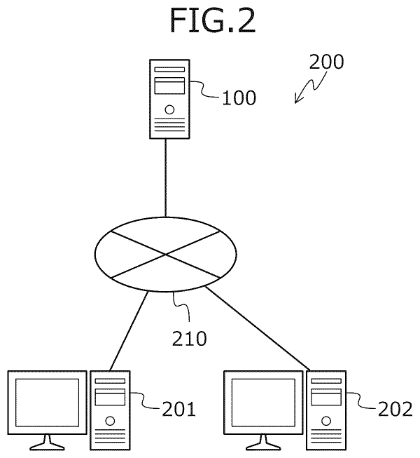

Next, an example of an information processing system 200 to which the information processing device 100 shown in FIG. 1 is applied is described with reference to FIG. 2.

FIG. 2 is an explanatory diagram depicting an example of the information processing system 200. In FIG. 2, the information processing system 200 includes the information processing device 100, a numerical calculation device 201, and a client device 202.

In the information processing system 200, the information processing device 100 and the client device 202 are connected via a wired or wireless network 210. The network 210 is, for example, a local area network (LAN), a wide area network (WAN), the Internet, etc. In the information processing system 200, the information processing device 100 and the numerical calculation device 201 are connected via the wired or wireless network 210.

The information processing device 100 is a computer that manages density functional theory calculations. The information processing device 100 receives, for example, a calculation instruction from the client device 202. The calculation instruction specifies a problem to be calculated. The information processing device 100 sets a first condition that can be a convergence condition for density functional theory calculations. The first condition is, for example, that the difference ratio of the total electron energy based on the most-recently updated electron density to the representative value of the total electron energy based on the electron density updated in the initial period of the density functional theory calculation is not more than a first threshold value. The difference ratio is, for example, a value obtained by dividing the difference of the total electron energy based on the most-recently updated electron density and the representative value of the total electron energy based on the electron density updated until the immediately preceding time, by the representative value of the total electron energy based on the initially updated electron density.

In addition to the first condition, the information processing device 100 sets a second condition that can be a convergence condition for the density functional theory calculation. The second condition is that the difference of the most-recently calculated electron density and the immediately precedingly calculated electron density is not more than a second threshold. In response to the calculation instruction, the information processing device 100 performs the density functional theory calculation based on the first and second conditions that can be the set convergence conditions for the density functional theory calculation. The information processing device 100 performs the density functional theory calculation so as to repeatedly update the electron density until at least one of the first and second conditions is satisfied. This allows the information processing device 100 to identify the final electron density. When at least one of the first condition and the second condition, which can be a convergence condition for the density functional theory calculation, is satisfied, the information processing device 100 transmits the final electron density to the client device 202.

Here, the information processing device 100 may, for example, perform distributed processing of the density functional theory calculation with the numerical calculation device 201. The information processing device 100 transmits a processing request for the density functional theory calculation to the numerical calculation device 201. The information processing device 100 may receive the final electron density from the numerical calculation device 201 and transmit the final electron density to the client device 202. The information processing device 100 is, for example, a server or a PC.

The numerical calculation device 201 is a computer that shares the density functional theory calculation. In response to receiving the processing request, the numerical calculation device 201 may perform the density functional theory calculation. The numerical calculation device 201 performs the density functional theory calculation and transmits the obtained result as the final electron density to the information processing device 100. The numerical calculation device 201 is, for example, a server or a PC.

The client device 202 is a computer that transmits a calculation instruction to the information processing device 100 based on an operation input by a user. When the client device 202 receives the final electron density from the information processing device 100, the client device 202 outputs the final electron density so that the user can refer to it. The client device 202 is, for example, a PC, a tablet terminal, or a smartphone. In the following description, a case where the information processing device 100 operates independently is mainly described.

For example, in the field of material development, the information processing device 100 is considered to be applied to a case where a structural relaxation calculation is performed in which density functional theory calculations are repeated multiple times in order to obtain a stable structure of a molecule that governs the properties of a substance. For example, the information processing device 100 is considered to be applied to a case where a structural relaxation calculation is performed in which density functional theory calculations are repeated multiple times for materials informatics, and where useful material data is accumulated for a stable structure of a molecule.

The structural relaxation calculation is, for example, a series of processes for obtaining a stable structure of a molecule. The structural relaxation calculation corresponds to, for example, an iterative solution method. The iterative solution method is, for example, a method of repeatedly performing a specific operation until it is determined that a solution has converged. Convergence is, for example, a state in which a calculated solution becomes equal to or smaller than a threshold value. The structural relaxation calculation is a calculation for obtaining a stable structure of a molecule by, for example, repeatedly carrying out, until the convergence condition is satisfied while updating the three-dimensional structure of the molecule, a series of processes of performing the density functional theory calculation for calculating the electron density, and calculating the magnitude of the force acting on the atom based on the electron density. The convergence condition is a condition for determining that a solution has converged. The convergence condition is, for example, that the most-recently calculated magnitude of the force acting on the atom becomes equal to or smaller than a threshold value. In this case, the information processing device 100 may properly use the first condition and the second condition separately in each of plural times that the density functional theory calculation is performed.

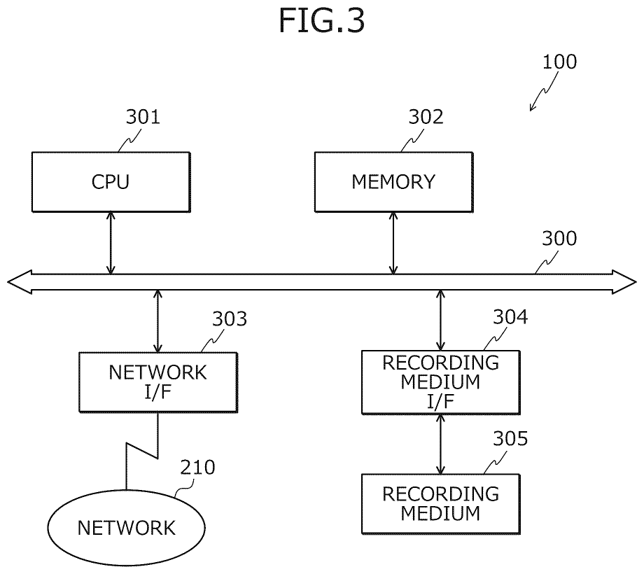

Next, an example of a hardware configuration of the information processing device 100 is described with reference to FIG. 3.

FIG. 3 is a block diagram of an example of a hardware configuration of the information processing device 100. In FIG. 3, the information processing device 100 has a central processing unit (CPU) 301, a memory 302, a network interface (I/F) 303, a recording medium I/F 304, and a recording medium 305. Further, the components are connected to each other by a bus 300.

Here, the CPU 301 governs overall control of the information processing device 100. The memory 302, for example, includes a read-only memory (ROM), a random access memory (RAM), and a flash-ROM. In particular, for example, the flash-ROM and/or ROM stores therein various programs and the RAM is used as a work area of the CPU 301. Programs stored to the memory 302 are loaded onto the CPU 301, whereby encoded processes are executed by the CPU 301.

The network I/F 303 is connected to the network 210 via a communications line and is connected to other computers through the network 210. Further, the network I/F 303 administers an internal interface with the network 210 and controls the input and output of data with respect to the other computers. The network I/F 303, for example, is a modem, a LAN adapter, or the like.

The recording medium I/F 304 controls the reading and writing of data with respect to the recording medium 305 under the control of the CPU 301. The recording medium I/F 304 is, for example, a disc drive, a solid-state drive (SSD), a universal serial bus (USB) port, or the like. The recording medium 305 is a nonvolatile memory storing data written thereto under the control of the recording medium I/F 304. The recording medium 305 is, for example, a disc, a semiconductor memory, a USB memory, or the like. The recording medium 305 may be removable from the information processing device 100.

In addition to the components above, the information processing device 100 may include, for example, a keyboard, a mouse, a display, a printer, a scanner, a microphone, a speaker, etc. Further, the information processing device 100 may further have the recording medium I/F 304 and/or the recording medium 305 in plural. The information processing device 100 may omit the recording medium I/F 304 and/or the recording medium 305.

An example of a hardware configuration of the numerical calculation device 201 is the same as the example of the hardware configuration of the information processing device 100 depicted in FIG. 3 and thus, description thereof is omitted herein.

An example of a hardware configuration of the client device 202 is the same as the example of the hardware configuration of the information processing device 100 depicted in FIG. 3 and thus, description thereof is omitted herein.

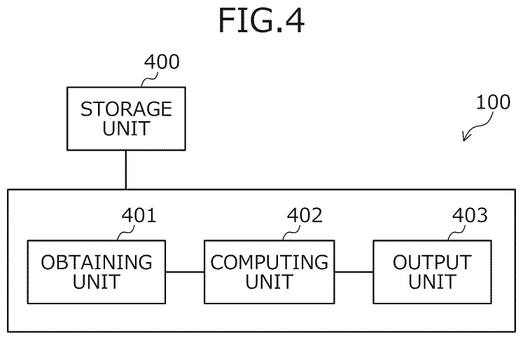

Next, an example of a functional configuration of the information processing device 100 is described with reference to FIG. 4.

FIG. 4 is a block diagram depicting an example of the functional configuration of the information processing device 100. Information processing device 100 includes a storage unit 400, an obtaining unit 401, a computing unit 402, and an output unit 403.

The storage unit 400 is implemented by, for example, a storage area such as the memory 302 or the recording medium 305 depicted in FIG. 3. Hereinafter, a case where the storage unit 400 is included in the information processing device 100 is described, but this is not limitative. For example, the storage unit 400 may be included in a device different from the information processing device 100, and the stored contents of the storage unit 400 may be accessed by the information processing device 100.

The obtaining unit 401 to the output unit 403 function as an example of a controller. For example, respective functions of the obtaining unit 401 to the output unit 403 are implement by, for example, the CPU 301 executing a program stored in a storage area such as the memory 302 or the recording medium 305 depicted in FIG. 3, or by a network I/F 303. The processing results of each functional unit are stored in a storage area such as the memory 302 or the recording medium 305 depicted in FIG. 3.

The storage unit 400 stores various pieces of information that are referred to or updated in the processing performed by each functional unit. The storage unit 400 stores, for example, a first condition that can be a convergence condition for density functional theory calculation. The first condition is, for example, that the difference ratio of the total electron energy based on the most-recently updated electron density to the representative value of the total electron energy based on the electron density updated in the initial period of the density functional theory calculation is not more than a first threshold value. The electron density is, for example, the electron density at each point in a specified space.

The difference ratio is, for example, a value obtained by dividing the difference of the total electron energy based on the most-recently updated electron density and the representative value of the total electron energy based on the electron density updated until the immediately preceding time, by the representative value of the total electron energy based on the initially updated electron density. The difference ratio is, for example, the absolute value of a value obtained by dividing the difference of the total electron energy based on the most-recently updated electron density and the representative value of the total electron energy based on the electron density updated until the immediately preceding time, by the representative value of the total electron energy based on the initially updated electron density.

The initial period is, for example, a period from the point of time when the electron density is updated for the first time to the point of time when the electron density is updated a predetermined number of times. The initial period may be, for example, only the point of time when the electron density is updated for the first time. The representative value is, for example, a statistical value. The statistical value is, for example, a maximum value, a minimum value, an average value, a mode value, or a median value. The representative value of the total electron energy based on the electron density updated until the immediately preceding time may be, for example, any one of the total electron energies based on the electron density updated until the immediately preceding time. The representative value of the total electron energy based on the initially updated electron density may be, for example, any one of the total electron energies based on the initially updated electron density.

The difference ratio is, for example, a value obtained by dividing the difference of the total electron energy based on the most-recently updated electron density and the representative value of the total electron energy based on the electron density updated until the immediately preceding time, by the representative value of the total electron energy based on the initially updated electron density. For example, the difference ratio is the absolute value of a value obtained by dividing the difference of the total electron energy based on the most-recently updated electron density and the representative value of the total electron energy based on the electron density updated until the immediately preceding time, by the representative value of the total electron energy based on the initially updated electron density. The first condition is obtained, for example, by the obtaining unit 401. The first condition may be set, for example, by a user in advance.

The storage unit 400 stores, for example, a second condition that may be a convergence condition for density functional theory calculation. The second condition is that the difference of the most-recently calculated electron density and the immediately precedingly calculated electron density is not more than a second threshold. The second condition is obtained, for example, by the obtaining unit 401. The second condition may be set, for example, by a user in advance.

The storage unit 400 may store, for example, a convergence condition for a structural relaxation calculation utilizing density functional theory calculation. The convergence condition for the structural relaxation calculation is, for example, that the calculated magnitude of the force acting on the atom is not more than a threshold value. The convergence condition is obtained, for example, by the obtaining unit 401. The convergence condition may be set, for example, by a user in advance.

The obtaining unit 401 obtains various types of information used in the processing by each functional unit. The obtaining unit 401 stores the various types of obtained information into the storage unit 400, or outputs the information to the functional units. The obtaining unit 401 may also output various types of information stored in the storage unit 400 to the functional units. The obtaining unit 401 obtains various types of information based on, for example, an operation input by a user. The obtaining unit 401 may receive various types of information from, for example, a device different from the information processing device 100.

The obtaining unit 401 obtains, for example, a first condition. For example, the obtaining unit 401 obtains the first condition by receiving an input of the first condition based on an operation input by a user. For example, the obtaining unit 401 may receive the first condition from another computer and thereby obtains the first condition.

The obtaining unit 401 may obtain, for example, a second condition. For example, the obtaining unit 401 obtains the second condition by receiving an input of the second condition based on an operation input by a user. For example, the obtaining unit 401 may receive the second condition from another computer and thereby obtains the second condition.

The obtaining unit 401 may obtain, for example, a convergence condition related to the structural relaxation calculation. The obtaining unit 401, for example, obtains the convergence condition by receiving an input of the convergence condition based on an operation input by a user. For example, the obtaining unit 401 receives the convergence condition from another computer and thereby obtains the convergence condition.

The obtaining unit 401 obtains, for example, a calculation instruction. The calculation instruction specifies a problem to be calculated. For example, the obtaining unit 401 obtains the calculation instruction by receiving an input of the calculation instruction based on an operation input by a user. For example, the obtaining unit 401 receives the calculation instruction from another computer and thereby obtains the calculation instruction.

The obtaining unit 401 may receive a start trigger for starting the processing of any of the functional units. The start trigger may be, for example, a predetermined operation input by a user. The start trigger may be, for example, predetermined information received from another computer. The start trigger may be, for example, predetermined information output by any of the functional units. The obtaining unit 401 may receive the calculation instruction as a start trigger for starting the processing of the computing unit 402.

The computing unit 402 performs density functional theory calculations. The computing unit 402 performs density functional theory calculations, for example, by repeatedly updating the electron density until a first condition is satisfied. The first condition is, for example, that the difference ratio of the total electron energy based on the most-recently updated electron density to the representative value of the total electron energy based on the electron density updated in the initial period of the density functional theory calculation is not more than a first threshold.

The difference ratio is, for example, a value obtained by dividing the difference of the total electron energy based on the most-recently updated electron density and the representative value of the total electron energy based on the electron density updated until the immediately preceding time, by the representative value of the total electron energy based on the initially updated electron density. For example, the difference ratio is the absolute value of a value obtained by dividing the difference of the total electron energy based on the most-recently updated electron density and the representative value of the total electron energy based on the electron density updated until the immediately preceding time, by the representative value of the total electron energy based on the initially updated electron density.

The initial period is, for example, a period from the point of time when the electron density is first updated to the point of time when the electron density is updated a predetermined number of times. The initial period may be, for example, only the point of time when the electron density is first updated. The representative value is, for example, a statistical value. The statistical value is, for example, a maximum value, a minimum value, an average value, a mode value, or a median value. The representative value of the total electron energy based on the electron density updated until the immediately preceding time may be, for example, any one of the total electron energies based on the electron density updated until the immediately preceding time. The representative value of the total electron energy based on the electron density initially updated may be, for example, any one of the total electron energies based on the electron density initially updated.

The difference ratio is, for example, a value obtained by dividing the difference of the total electron energy based on the most-recently updated electron density and the representative value of the total electron energy based on the electron density updated until the immediately preceding time, by the representative value of the total electron energy based on the initially updated electron density. For example, the difference ratio is the absolute value of a value obtained by dividing the difference of the total electron energy based on the most-recently updated electron density and the representative value of the total electron energy based on the electron density updated until the immediately preceding time, by the representative value of the total electron energy based on the initially updated electron density.

The computing unit 402 ends the density functional theory calculation when, for example, the first condition is satisfied. This allows the computing unit 402 to reduce the processing time required to perform the density functional theory calculation. In addition, since the computing unit 402 defines the difference ratio with respect to the representative value of the total electron energy based on the electron density updated in the initial period of the density functional theory calculation, a common value can be set for the first threshold value to be compared with the difference ratio, irrespective of the problem to be calculated. Hence, the computing unit 402 can maintain the accuracy of determining whether the solution has converged in the density functional theory calculation, irrespective of the problem to be calculated, thereby improving convenience.

The computing unit 402 may perform density functional theory calculations, for example, so as to repeatedly update the electron density until at least one of the first condition and the second condition is satisfied. The second condition is that the difference of the most-recently updated electron density and the electron density updated until the immediately preceding time is not more than a second threshold. The computing unit 402 ends the density functional theory calculation when at least one of the first condition and the second condition is satisfied, for example. This allows the computing unit 402 to reduce the processing time required when performing density functional theory calculations.

The computing unit 402 may perform density functional theory calculations, for example, so as to repeatedly update the electron density until the second condition is satisfied without referring to the first condition. The computing unit 402 ends the density functional theory calculation when the second condition is satisfied, for example. This allows the computing unit 402 to easily update the electron density with high accuracy when performing density functional theory calculations.

The computing unit 402 may properly use the first condition and the second condition separately, for example, in the process of the density functional theory calculation. For example, the computing unit 402 performs the density functional theory calculation so as to repeatedly update the electron density unless the second condition is satisfied in the initial period of the density functional theory calculation. For example, the computing unit 402 ends the density functional theory calculation when the second condition is satisfied.

For example, if the second condition is not satisfied in the initial period of the density functional theory calculation, the computing unit 402 performs the density functional theory calculation so as to repeatedly update the electron density after the initial period of the density functional theory calculation unless the first condition is satisfied. For example, the computing unit 402 may end the density functional theory calculation when the first condition is satisfied. This allows the computing unit 402 to reduce the amount of processing.

Furthermore, for example, the computing unit 402 will update the electron density by repeatedly performing a series of processes after setting the electron density to an initial state, to calculate the final electron density. The series of processes includes, for example, a process a for calculating and updating the electron density using a one-electron wave function derived by solving the Kohn-Sham equation based on the current electron density. The series of processes includes, for example, a process b performed subsequent to the process a. The process b includes calculating a difference between the electron density immediately before the update and the electron density immediately after the update.

The series of processes includes a process c performed subsequent to the process b. The process c includes calculating a total electron energy as a physical characteristic value based on the electron density immediately after the update. The process c includes calculating a difference between the total electron energy based on the electron density immediately after the current update and a representative value of the total electron energy based on the electron density updated until the time immediately preceding the current update. The electron density immediately after the current update corresponds to the electron density updated most recently as described above. The electron density updated until the immediately preceding time and to be currently updated corresponds to the above electron density updated until the immediately preceding time. The process c includes calculating a difference ratio by dividing the calculated difference by a representative value of the total electron energy based on the electron density initially updated. The initial period is, for example, the first time. The initial period may be, for example, a time from the first time to a predetermined time.

For example, when carrying out the series of processes, if the convergence condition for the density functional theory calculation is not satisfied, the computing unit 402 performs the series of processes again to repeat the series of processes. The convergence condition for the density functional theory calculation is, for example, the first condition. The first condition corresponds to, for example, the calculated difference ratio being not more than a first threshold.

The convergence condition for the density functional theory calculation may be, for example, satisfaction of at least one of the first condition and the second condition. The second condition is, for example, that the difference of the most-recently calculated electron density and the electron density calculated immediately before is not more than a second threshold. The electron density calculated immediately before is, for example, the electron density immediately before updating. The most-recently calculated electron density is, for example, the electron density immediately after updating. The second condition corresponds to, for example, the difference of the electron density immediately before updating and the electron density immediately after updating being not more than a second threshold. The convergence condition for the density functional theory calculation may be, for example, the second condition.

The computing unit 402 may have a function of performing certain calculation processing utilizing the density functional theory calculation. The certain calculation processing is, for example, a structural relaxation calculation. The structural relaxation calculation is performed by performing the density functional theory calculation multiple times. Hereinafter, a case is described where the computing unit 402 performs a structural relaxation calculation, but the present invention is not limited hereto. For example, other than the structural relaxation calculation, the computing unit 402 may perform other calculation processing utilizing the density functional theory calculation.

For example, the computing unit 402 performs the density functional theory calculation so as to repeatedly update the electron density, until the first condition is satisfied, in a specified execution among the multiple executions of the density functional theory. The specified execution is, for example, at least any execution among the multiples executions of the density functional theory calculation. The specified execution is, for example, the first execution. The specified execution may be, for example, the second execution or a subsequent execution. The specified execution may be, for example, each of multiple executions.

As a result, the computing unit 402 can reduce the processing time required for performing the density functional theory calculation in a specified execution, and can easily reduce the processing time required for performing the structural relaxation calculation. In addition, since the computing unit 402 defines the difference ratio with respect to a representative value of the total electron energy based on the electron density updated in the initial period of the density functional theory calculation, a common value can be set for the first threshold value to be compared with the difference ratio, irrespective of the problem to be calculated. Hence, the computing unit 402 can maintain the accuracy of determining whether a solution has converged in the density functional theory calculation, irrespective of the problem to be calculated, achieving improved convenience.

For example, the computing unit 402 may perform a density functional theory calculation such that, in at least a specified execution among the multiple executions the density functional theory calculation, the electron density is repeatedly updated until at least one of the first condition and the second condition is satisfied. As a result, the computing unit 402 can reduce the processing time required for performing a density functional theory calculation in a specified execution, and can easily reduce the processing time required for performing a structural relaxation calculation.

The computing unit 402 may perform density functional theory calculations, for example, in such a manner that, in each of the plural times of performing density functional theory calculations, other than the specified execution, the electron density is repeatedly updated until the second condition is satisfied without referring to the first condition. This allows the computing unit 402 to easily update the electron density with high accuracy when performing density functional theory calculations in any time other than the specified execution, and makes it easy to accurately obtain a stable structure of a molecule when performing a structural relaxation calculation.

The computing unit 402 may perform density functional theory calculations, for example, such that in each of the executions of the density functional theory calculation before the specified execution, the electron density is repeatedly updated until at least one of the first condition and the second condition is satisfied. This allows the computing unit 402 to reduce the processing time required for performing each of the executions of the density functional theory calculation before the specified execution, and makes it easy to reduce the processing time required for performing a structural relaxation calculation.

The computing unit 402 may perform density functional theory calculations, for example, in such a way that in each execution of the density functional theory calculation after a specified execution, the computing unit 402 repeatedly updates the electron density until the second condition is satisfied without referring to the first condition. This allows the computing unit 402 to easily update the electron density with high accuracy when performing the density functional theory calculation in each execution after the specified execution, and allows the computing unit 402 to easily obtain a stable structure of the molecule with high accuracy when performing a structural relaxation calculation.

For example, the computing unit 402 initializes the structure of the molecule by initializing the atomic positions, and then repeatedly performs a series of processes. The series of processes includes, for example, a process A for performing density functional theory calculations based on the atomic positions in the structure of the molecule. For example, when performing the density functional theory calculation in a specified execution out of the multiple executions, the process A sets a first condition as a convergence condition for the density functional theory calculation. The specified execution is, for example, any one of the executions of the density functional theory calculation. The specified execution is, for example, the first execution. The specified execution may be, for example, the second execution or a subsequent execution. The specified execution may be, for example, each of multiple executions.

When performing a specified execution of the density functional theory calculation among the multiple executions thereof, the process A may set the convergence condition for the density functional theory calculation to satisfy at least one of the first condition and the second condition. In any execution of the density functional theory calculation other than the specified execution among the multiple executions thereof, the process A may set the second condition for the convergence condition for the density functional theory calculation.

In executions of the density functional theory calculation before the specified execution among the multiple executions thereof, the process A may set the first condition for the convergence condition for the density functional theory calculation. In each execution of the density functional theory calculation before the specified execution, the process A may set the convergence condition for the density functional theory calculation to satisfy at least one of the first condition and the second condition. In each execution of the density functional theory calculation after the specified execution among the multiple executions thereof, the process A may set the second condition for the convergence condition for the density functional theory calculation.

The series of processes includes, for example, a process B performed subsequent to the process A. The process B includes calculating the total electron energy based on the electron density at each point in the space calculated in the density functional theory calculation. The series of processes includes, for example, a process C performed after the process B. The process C includes judging whether the convergence condition for the structural relaxation calculation is satisfied. The process C includes updating the atomic positions when the convergence condition for the structural relaxation calculation is not satisfied. For example, when the series of processes is performed, if the convergence condition for the structural relaxation calculation is not satisfied, the computing unit 402 performs the series of processes again, thereby repeatedly performing the series of processes.

This allows the computing unit 402 to perform the structural relaxation calculation and to obtain a stable structure of the molecule. In each execution of a density functional theory calculation of the multiple executions thereof, the computing unit 402 can use the first condition and the second condition separately as the convergence condition for the density functional theory calculation. Therefore, the computing unit 402 can reduce the processing time required to perform the structural relaxation calculation, for example.

The output unit 403 outputs the processing result of at least one of the functional units. The output format is, for example, display on a display, print output to a printer, transmission to an external device by the network I/F 303, or storage to a storage area such as the memory 302 or the recording medium 305. In this way, the output unit 403 can notify a user of the processing result of at least one of the functional units, and can improve the convenience of the information processing device 100.

For example, the output unit 403 may output the final electron density or the final total electron energy obtained as a result of the density functional theory calculation performed by the computing unit 402 so that the user can refer to it. For example, the output unit 403 may transmit the final electron density or the final total electron energy obtained as a result of the density functional theory calculation performed by the computing unit 402 to another computer. In this way, the output unit 403 can make the electron density or the total electron energy externally accessible.

The output unit 403 may output, for example, the result of the structural relaxation calculation performed by the computing unit 402 so that the user can refer to it. The output unit 403 may transmit, for example, the result of the structural relaxation calculation performed by the computing unit 402 to another computer. In this way, the output unit 403 can make the result of the structural relaxation calculation performed by the computing unit 402 externally accessible.

The output unit 403 may, for example, output the stable structure of the molecule obtained as a result of the structural relaxation calculation performed by the computing unit 402 so that the user can refer to it. The output unit 403, for example, outputs the stable structure of the molecule obtained as a result of the structural relaxation calculation performed by the computing unit 402 so that the user can refer to it. In this way, the output unit 403 can make the stable structure of the molecule externally accessible.

The output unit 403 may, for example, output the total electron energy obtained as a result of the structural relaxation calculation performed by the computing unit 402 so that the user can refer to it. For example, the output unit 403 may transmit the total electron energy obtained as a result of the structural relaxation calculation performed by the computing unit 402 to another computer. This allows the output unit 403 to make the total electron energy available for external reference.

Here, while a case where the information processing device 100 includes the obtaining unit 401, the computing unit 402, and the output unit 403 has been described, configuration is not limited hereto. For example, the information processing device 100 may omit any of the functional units. For example, the information processing device 100 may cooperate with another computer including any of the functional units. The other computer is, for example, the numerical calculation device 201.

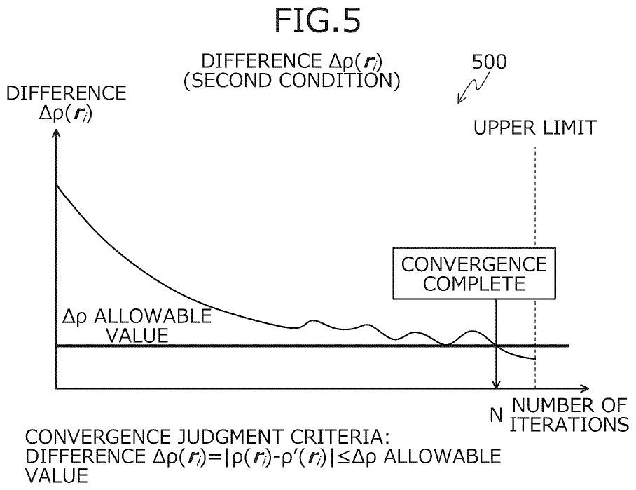

An example of operation of the information processing device 100 is described with reference to FIGS. 5 to 8.

FIGS. 5, 6, 7, and 8 are explanatory diagrams of an example of operation of the information processing device 100. In FIGS. 5 to 8, the information processing device 100 performs density functional theory calculations. When performing density functional theory calculations, the information processing device 100 sets satisfying at least one of the first condition and the second condition as a convergence condition for the density functional theory calculation.

The first condition represents that the difference ratio RDE of the total electron energy is not more than an allowable value RDE_TH. The difference ratio RDE is, for example, the absolute value of a value obtained by dividing the difference of the total electron energy based on the most-recently updated electron density and the representative value of the total electron energy based on the electron density updated until the immediately preceding time, by the representative value of the total electron energy based on the initially updated electron density.

The allowable value RDE_TH is, for example, set in advance by the user. Here, RDE_TH is assumed to be, for example, 1.0e−5. The representative value is, for example, a statistical value. The statistical value is, for example, the maximum value, minimum value, average value, mode value, or median value related to the electron density calculated up to the immediately preceding time. The initial period is, for example, the first execution. The initial period may be, for example, from the first execution to a predetermined execution.

The representative value of the total electron energy based on the electron density updated until the immediately preceding time may be, for example, any one of the total electron energies based on the electron density updated until the immediately preceding time. The representative value of the total electron energy based on the electron density updated until the immediately preceding time may be, for example, the total electron energy based on the electron density calculated at any time point up to the immediately preceding time.

The representative value of the total electron energy based on the electron density updated initially may be, for example, any one of the total electron energies based on the electron density updated initially. The representative value of the total electron energy based on the electron density updated initially may be, for example, the total electron energy based on the electron density calculated at any time point in the early stages.

The second condition represents that for all points rᵢ in the space, the absolute difference Δρ(rᵢ)=|electron density ρ(rᵢ)-electron density ρ′(rᵢ)| between the most-recently calculated electron density ρ′(rᵢ) and the immediately precedingly calculated electron density ρ(rᵢ) is not more than a Δρ allowable value. The Δρ allowable value is, for example, set in advance by a user. The Δρ allowable value is assumed to be, for example, 1.0. The information processing device 100 performs density functional theory calculations by repeatedly performing the process of calculating the electron density until the convergence condition for the density functional theory calculation is satisfied.

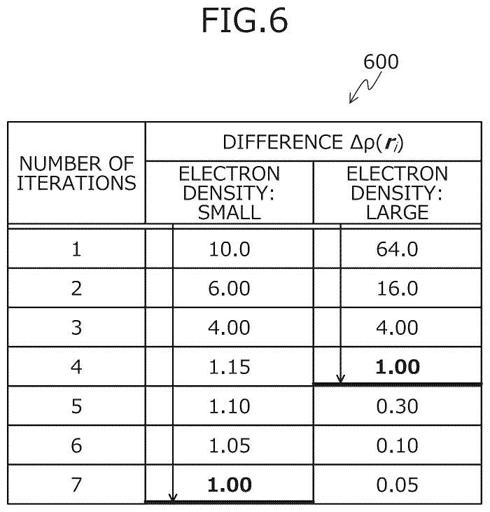

Here, moving to the explanation of FIGS. 5 and 6, the timing at which the second condition is satisfied is explained. A graph 500 in FIG. 5 shows the change in Δρ(rᵢ) when the process of calculating the electron density is repeated, and shows the timing at which the second condition is satisfied. The horizontal axis of the graph 500 shows, for example, the number of iterations. The number of iterations is the number of times that the process of calculating the electron density is repeated. The vertical axis of the graph 500 shows Δρ(rᵢ). As shown in the graph 500, the number of times that the process of calculating the electron density is repeated until the second condition is satisfied is N. N is relatively close to the upper limit of the number of times that the process of calculating the electron density is repeated.

A table 600 in FIG. 6 shows specific values of Δρ(rᵢ) when the process of calculating the electron density is repeated, and shows the timing at which the second condition is satisfied. As shown in table 600, Δρ(rᵢ) corresponding to a point rᵢ where the electron density ρs(rᵢ) is relatively small is less likely to be smaller than the Δρ allowable value, compared to Δρ(rᵢ) corresponding to a point rᵢ where the electron density ρ(rᵢ) is relatively large. Therefore, as shown in table 600, the number of times N for repeating the process of calculating the electron density until the second condition is satisfied tends to be a relatively large number, for example, 7.

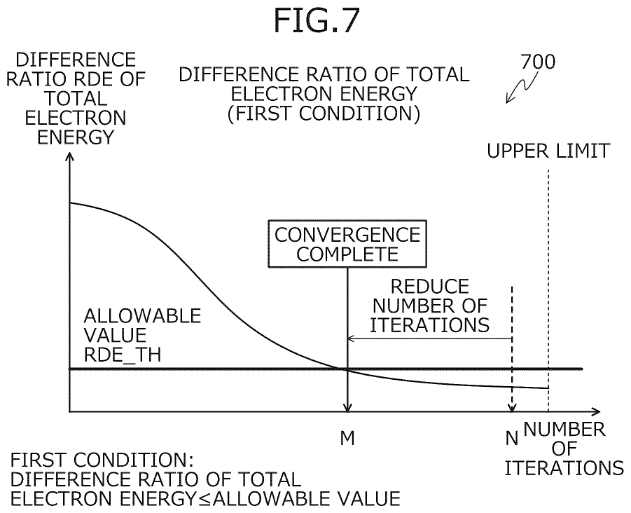

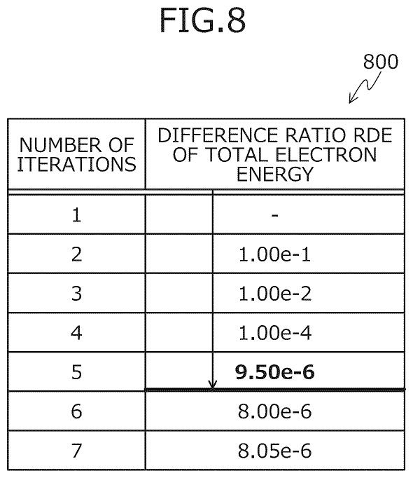

Next, moving to the explanation of FIG. 7 and FIG. 8, the timing for satisfying the first condition is explained. A graph 700 in FIG. 7 shows the change in RDE when the process of calculating the electron density is repeated, and shows the timing for satisfying the first condition. The horizontal axis of the graph 700 indicates, for example, the number of iterations. The number of iterations is the number of times that the process of calculating the electron density is repeated. The vertical axis of the graph 700 indicates the RDE. As shown in the graph 700, the number of times for repeating the process of calculating the electron density until the first condition is satisfied is M. M is not more than N, and is relatively far from the upper limit of the number of times that the process of calculating the electron density is repeated.

A table 800 in FIG. 8 shows specific values of RDE when the process of calculating the electron density is repeated, and shows the timing at which the first condition is satisfied. As shown in the table 800, RDE is likely to be smaller than the allowable value RDE_TH. Thus, as shown in table 800, the number of times M that the process of calculating the electron density is repeated until the first condition is satisfied is, for example, 5. M is a value smaller than N.

As a result, the information processing device 100 sets, as the convergence condition, that at least one of the first condition and the second condition is satisfied, so that the number of times that the process of calculating the electron density is repeated when performing density functional theory calculations can be reduced. For example, the information processing device 100 can suppress the number of times by which the process of calculating the electron density is repeated to M times instead of N times. Therefore, the information processing device 100 can reduce the processing time required when performing density functional theory calculations.

For example, a conventional method may be considered in which the first condition is not used as the convergence condition, and only the second condition is used. In this conventional method, the number of times that the process of calculating the electron density is repeated is N times. Therefore, the conventional method leads to an increase in the processing time required to perform density functional theory calculations. Compared to the conventional method, the information processing device 100 can reduce the processing time required to perform density functional theory calculations.

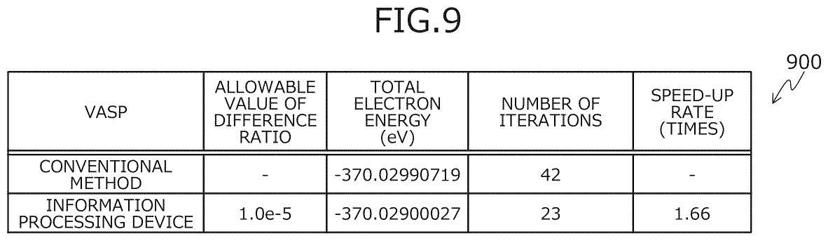

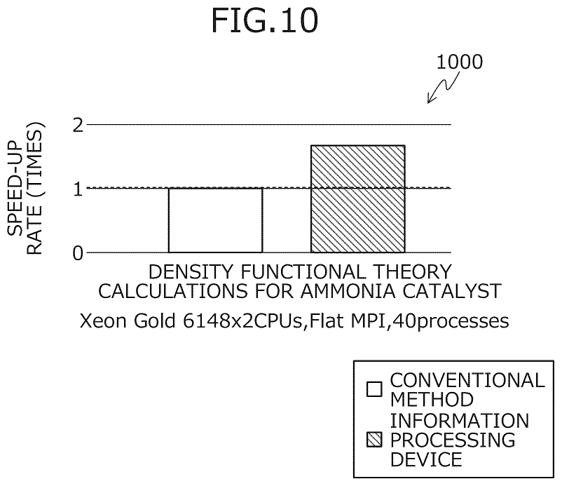

Next, an example of the effects of the information processing device 100 are described with reference to FIGS. 9 and 10.

FIGS. 9 and 10 are explanatory diagrams showing the results of a comparison with a conventional method. In FIGS. 9 and 10, it is assumed that the information processing device 100 performs density functional theory calculations using VASP (Vienna Ab initio Simulation Package) software. The VASP software is a non-empirical quantum molecular dynamics calculation program using pseudopotentials and a plane wave basis. It is assumed that the information processing device 100, for example, performs density functional theory calculations for an ammonia catalyst.

Table 900 in FIG. 9 shows a comparative example of calculation results between the information processing device 100 and the conventional method. The conventional method, for example, does not use the first condition as a convergence condition, but only uses the second condition. As shown in table 900, the conventional method calculates a total electron energy of −370.02990719 eV. In the conventional method, the number of iterations in the density functional theory calculation is 42. The number of iterations is the number of times that the process of calculating the electron density is repeated.

Meanwhile, the information processing device 100 sets the allowable value RDE_TH=1.0e-5. The information processing device 100 calculates a total electron energy of −370.02900027 eV. In the information processing device 100, the number of iterations in the density functional theory calculation is 23. The number of iterations is the number of times that the process of calculating the electron density is repeated. In this way, the information processing device 100 can speed up the density functional theory calculation by 1.66 times compared to the conventional method.

A graph 1000 in FIG. 10 shows a comparative example of the speed-up rate between the information processing device 100 and the conventional method. As shown in FIG. 10, the speed-up rate of the information processing device 100 is 1.66 times when the conventional method is set as the standard: 1. The information processing device 100 can speed up density functional theory calculations compared to the conventional method, and can suppress an increase in the processing time required to perform density functional theory calculations. The information processing device 100 can calculate the total electron energy with a difference of less than 0.001 eV, for example, compared to the conventional method.

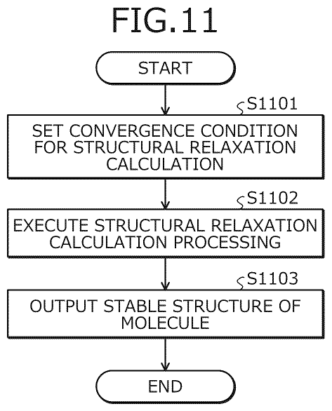

Next, various processing procedures when the information processing device 100 performs structural relaxation calculations utilizing density functional theory calculations are described with reference to FIGS. 11 to 13. In this case, the information processing device 100, for example, executes the overall processing described later in FIG. 11.

First, an example of the overall processing procedure executed by the information processing device 100 is described with reference to FIG. 11. The overall processing is implemented, for example, by the CPU 301 depicted in FIG. 3, storage areas such as the memory 302 and the recording medium 305, and the network I/F 303.

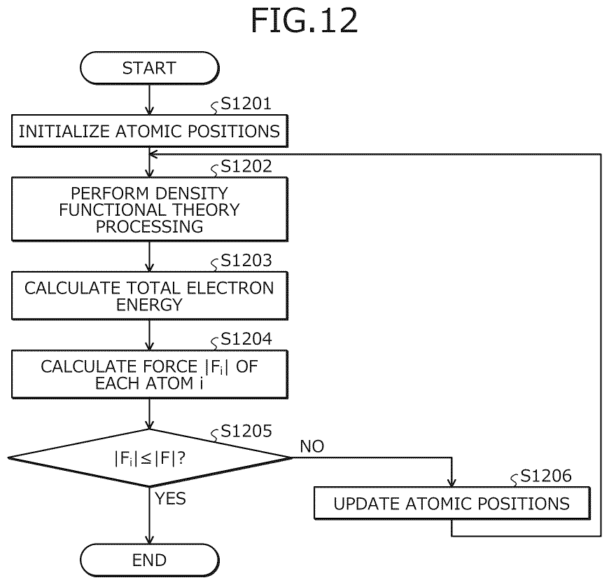

FIG. 11 is a flowchart showing an example of the overall processing procedure. In FIG. 11, the information processing device 100 sets a convergence condition for the structural relaxation calculation (step S1101). The information processing device 100 executes the structural relaxation calculation processing described later in FIG. 12 (step S1102). The information processing device 100 outputs the stable structure of the molecule (step S1103). The information processing device 100 ends the overall processing. As a result, the information processing device 100 can make the stable structure of the molecule available for reference by the user.

Next, an example of the structural relaxation calculation processing procedure executed by the information processing device 100 is described with reference to FIG. 12. The structural relaxation calculation processing is implemented by, for example, the CPU 301 depicted in FIG. 3, storage areas such as the memory 302 and the recording medium 305, and the network I/F 303.

FIG. 12 is a flowchart showing an example of the structural relaxation calculation processing procedure. In FIG. 12, the information processing device 100 initializes the structure of a molecule by initializing the atomic positions (step S1201).

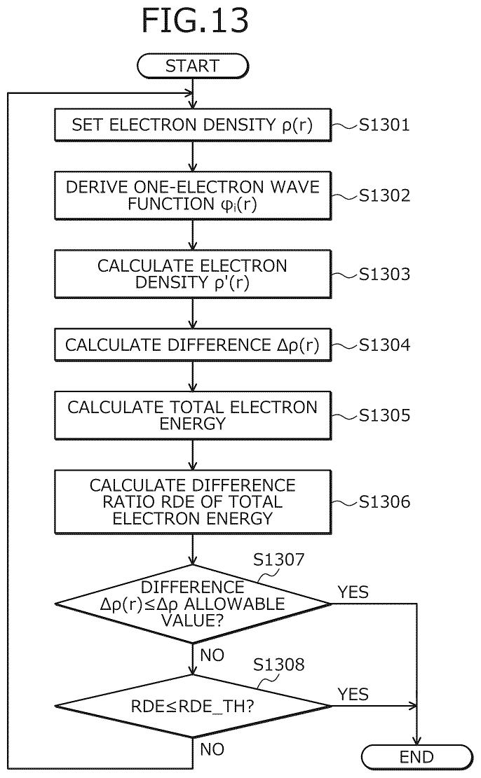

Based on the atomic positions, the information processing device 100 performs density functional theory processing, which is described later in FIG. 13 (step S1202). Based on the electron density at each point in space, the information processing device 100 calculates the total electron energy (step S1203). The information processing device 100 calculates a Force |Fᵢ| of each atom i (step S1204).

The information processing device 100 determines whether all |Fᵢ|≤|F| is satisfied (step S1205). |F| is set in advance by a user, for example. Here, when not all |Fᵢ|≤|F| but at least any of |Fi|>|F| is satisfied (step S1205: NO), the information processing device 100 proceeds to the process at step S1206.

At step S1206, the information processing device 100 updates the structure of the molecule by updating the atomic positions (step S1206), and returns to the process at step S1202. On the other hand, when all |Fᵢ|≤|F| is satisfied (step S1205: YES), the information processing device 100 ends the structural relaxation calculation process. This allows the information processing device 100 to obtain a stable structure of the molecule.

Next, an example of the density functional theory processing procedure executed by the information processing device 100 is described with reference to FIG. 13. The density functional theory processing is implemented by, for example, the CPU 301 depicted in FIG. 3, a storage area such as the memory 302 or the recording medium 305, and the network I/F 303.

FIG. 13 is a flowchart showing an example of the density functional theory processing procedure. In FIG. 13, the information processing device 100 sets the electron density ρ(r) (step S1301). For example, when there are plural points in the space, the information processing device 100 sets the electron density ρ(r) of each point. For example, in the first setting, the information processing device 100 sets an initial value of the electron density ρ(r). For example, in the second or subsequent setting, the information processing device 100 sets the electron density ρ(r) by a certain method. For example, in the second or subsequent setting, the information processing device 100 sets the electron density ρ(r) to the electron density ρ′(r) calculated immediately before.

The information processing device 100 solves the Kohn-Sham equation based on the electron density ρ(r) to derive the one-electron wave function φᵢ(r) (step S1302). For example, when there are multiple points in the space, the information processing device 100 derives the one-electron wave function φi(r) for each point. The information processing device 100 calculates the electron density ρ′(r) using the one-electron wave function φᵢ(r) (step S1303). For example, when there are multiple points in the space, the information processing device 100 calculates the electron density ρ′(r) for each point.

The information processing device 100 calculates the difference Δρ(r)=electron density ρ(r)-electron density ρ′(r) (step S1304). For example, when there are multiple points in the space, the information processing device 100 calculates the difference Δρ(r) for each point. The information processing device 100 calculates the total electron energy as a physical characteristic value based on the electron density ρ′(r) (step S1305). The information processing device 100 calculates the difference ratio RDE of the total electron energy (step S1306).

The information processing device 100 determines whether the difference Δρ(r) ≤Δρ allowable value is satisified (step S1307). For example, when there are multiple points in the space, the information processing device 100 determines whether the difference Δρ(r) of all the points is ≤Δρ allowable value. Here, when the difference Δρ(r) of all the points is ≤Δρ allowable value (step S1307: YES), the information processing device 100 ends the density functional theory processing. On the other hand, when the difference Δρ(r) of at least one of the points is >Δρ allowable value (step S1307: NO), the information processing device 100 proceeds to the processing at step S1308.

At step S1308, the information processing device 100 determines whether RDESRDE_TH is satisfied (step S1308). Here, when RDESRDE_TH is not satisfied (step S1308: NO), the information processing device 100 returns to the processing at step S1301. On the other hand, when RDESRDE_TH is satisfied (step S1308: YES), the information processing device 100 ends the density functional theory processing. This allows the information processing device 100 to perform density functional theory calculations.

The density functional theory processing shown in FIG. 13 implements, for example, the first density functional theory calculation performed by the information processing device 100. It is considered that the second and subsequent density functional theory calculations performed by the information processing device 100 are implemented by the density functional theory processing shown in FIG. 13 excluding the processing at step S1308, for example.

The information processing device 100 may independently perform only the density functional theory processing shown in FIG. 13 without performing the overall processing shown in FIG. 11. In other words, the information processing device 100 may independently perform only the density functional theory calculation without performing the structural relaxation calculation.

Here, the information processing device 100 may perform some steps of the processing of the flowcharts of FIG. 11 to FIG. 13 in an interchangeable sequence. For example, the processing sequence of steps S1304 and S1305 can be interchanged. Also, the information processing device 100 may omit some of the steps of the process of each of the flowcharts in FIG. 11 to FIG. 13.

As described above, the information processing device 100 can calculate the difference ratio of the total electron energy based on the most-recently updated electron density to the representative value of the total electron energy based on the initially updated electron density in the density functional theory calculation in which the electron density is repeatedly updated. The information processing device 100 can repeatedly update the electron density until the calculated difference ratio satisfies the first condition indicating that it is equal to or less than the first threshold. This allows the information processing device 100 to reduce the processing time required to perform the density functional theory calculation.

The information processing device 100 can repeatedly update the electron density until satisfying at least one of the first condition and the second condition indicating that the difference of the most-recently updated electron density and the electron density updated until the immediately preceding time is not more than the second threshold. This allows the information processing device 100 to reduce the processing time required to perform the density functional theory calculation.

According to the information processing device 100, it is possible to calculate the difference of the total electron energy based on the most-recently updated electron density and the representative value of the total electron energy based on the electron density updated until the immediately preceding time. According to the information processing device 100, it is possible to calculate the difference ratio by dividing the calculated difference by the representative value of the total electron energy based on the initially updated electron density. As a result, the information processing device 100 can accurately calculate the difference ratio, and it is possible to easily determine whether the first condition is satisfied, and it is possible to accurately determine whether the density functional theory calculation is to be terminated.

According to the information processing device 100, it is possible to calculate the difference of the total electron energy based on the most-recently updated electron density and the representative value of the total electron energy based on the electron density updated until the immediately preceding time. According to the information processing device 100, it is possible to calculate the difference ratio by dividing the calculated difference by the representative value of the total electron energy based on the initially updated electron density. Consequently, the information processing device 100 can accurately calculate the difference ratio, and it is possible to easily determine whether the first condition is satisfied, and it is possible to accurately determine whether the density functional theory calculation is to be terminated.

According to the information processing device 100, it is possible to perform density functional theory calculations so as to repeatedly update the electron density using the Kohn-Sham equation that enables calculation of a one-electron wave function. As a result, the information processing device 100 can appropriately implement density functional theory calculations.

According to the information processing device 100, it is possible to perform density functional theory calculations so as to repeatedly update the electron density of each point in a specified space. The information processing device 100 can thus be applied to cases where multiple points exist in a specified space.

According to the information processing device 100, when performing a structural relaxation calculation in which density functional theory calculation is performed multiple times, in at least one of the multiple density functional theory calculations, the electron density can be repeatedly updated until the first condition is satisfied. This allows the information processing device 100 to perform a structural relaxation calculation utilizing density functional theory calculation. The information processing device 100 can reduce the processing time required to perform a structural relaxation calculation.

The information processing method described in the present embodiment may be implemented by executing a prepared program on a computer such as a personal computer and a workstation. The program is stored on a non-transitory, computer-readable recording medium such as a hard disk, a flexible disk, a compact disc (CD)-ROM, a magneto optical (MO) disc, and a digital versatile disc (DVD), read out from the computer-readable medium, and executed by the computer. The program may be distributed through a network such as the Internet.

According to one aspect, it is possible to reduce the processing time required for performing density functional theory calculations.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A computer-readable recording medium storing therein an information processing program that causes a computer to execute a process in a density functional theory calculation in which electron density is repeatedly updated, the process comprising:
repeatedly updating the electron density until a first condition is satisfied, the first condition being that a difference ratio of a first value of a total electron energy to a second value of the total electron energy is not more than a first threshold, the first value of the total electron energy being based on a first value of the electron density updated most recently, and the second value of the total electron energy being based on a second value of the electron density updated in an initial period.

2. The recording medium according to claim 1, wherein
the electron density is repeatedly updated until at least one of the first condition and a second condition is satisfied, the second condition being that a difference of the first value of the electron density updated most recently and a third value of the electron density updated at an immediately preceding time is not more than a second threshold.

3. The recording medium according to claim 2, wherein
the third value of the electron density is updated until the immediately preceding time, and
the difference ratio is obtained by dividing a difference of the first value of the total electron energy and a third value of the total electron energy based on the third value of the electron density, by the second value of the total electron energy.

4. The recording medium according to claim 2, wherein
the third value of the electron density is updated until the immediately preceding time, and
the difference ratio is obtained by dividing a difference of the first value of the total electron energy and a third value of the total electron energy based on the third value of the electron density, by a fourth value of the total electron energy based on a fourth value of the electron density updated first.

5. The recording medium according to claim 1, wherein
the density functional theory calculation is a process of repeatedly updating the electron density using a Kohn-Sham equation that enables calculation of a one-electron wave function.

6. The recording medium according to claim 1, wherein
the density functional theory calculation is a process of repeatedly updating the electron density at each point in a specified space.

7. The recording medium according to claim 2, wherein
the process comprises, when performing a structural relaxation calculation in which the density functional theory calculation is performed a plurality of times, repeatedly updating the electron density in at least any one of the plurality of times of performing the density functional theory calculation until the first condition is satisfied.

8. An information processing method executed by a computer in a process in a density functional theory calculation in which electron density is repeatedly updated, the method comprising:
repeatedly updating the electron density until a first condition is satisfied, the first condition being that a difference ratio of a first value of a total electron energy to a second value of the total electron energy is not more than a first threshold, the first value of the total electron energy being based on a first value of the electron density updated most recently, and the second value of the total electron energy being based on a second value of the electron density updated in an initial period.

9. An information processing device, comprising:
a memory; and
a processor coupled to the memory, the processor configured to execute a process in a density functional theory calculation in which electron density is repeatedly updated, the process comprising:
repeatedly updating the electron density until a first condition is satisfied, the first condition being that a difference ratio of a first value of a total electron energy to a second value of the total electron energy is not more than a first threshold, the first value of the total electron energy being based on a first value of the electron density updated most recently, and the second value of the total electron energy being based on a second value of the electron density updated in an initial period.
